(19) United States
(12) Patent Application Publication
(10) Pub. No.: US 2025/0380593 A1
(43) Pub. Date: Dec. 11, 2025

(54) LIGHT EMITTING DEVICE AND METHOD FOR PRODUCING SAME

(71) Applicant: CANON KABUSHIKI KAISHA, Tokyo (JP)

(72) Inventors: YOSHIAKI TAGUCHI, Kanagawa (JP); KENTARO SUZUKI, Kanagawa (JP); AKINORI MAKAINO, Kanagawa (JP)

(21) Appl. No.: 19/311,424

(22) Filed: Aug. 27, 2025

Related U.S. Application Data
(63) Continuation of application No. PCT/JP2023/045969, filed on Dec. 21, 2023.

(30) Foreign Application Priority Data
Mar. 9, 2023 (JP) 2023-036733

(51) Int. Cl. H10K 59/131; H10K 59/12; H10K 59/80

(52) U.S. Cl. CPC H10K 59/131; H10K 59/1201; H10K 59/878

(57) ABSTRACT

A light-emitting device includes a first element and a second element on a substrate. Each of the first element and the second element includes a reflection portion, a first insulating layer, a first electrode, an organic layer including a luminescent layer, and a second electrode in this order from the substrate side, the first insulating layer has a depressed portion between the reflection portion of the first element and the reflection portion of the second element, and a conductor is disposed in the depressed portion.

### CROSS-REFERENCE TO RELATED APPLICATIONS

This application is a Continuation of International Patent Application No. PCT/JP2023/045969, filed on Dec. 21, 2023, which claims the benefit of Japanese Patent Application No. 2023-036733, filed on Mar. 9, 2023, both of which are hereby incorporated by reference herein in their entirety.

### BACKGROUND

### Field of the Technology

The technique of the present disclosure relates to a light-emitting device and a method for manufacturing the same.

### Description of the Related Art

An organic device including an organic functional layer containing an organic compound is known. Such an organic device is, for example, an organic light-emitting element including an organic electroluminescent (hereinafter, organic EL) film. Japanese Patent Laid-Open No. 2021-72282 describes a light-emitting device having a configuration in which a desired luminescent color is obtained for each pixel of B, G and R by passing light, emitted from an organic light-emitting element, through a color filter. In this light-emitting device, an optical resonance structure is constructed between a power supply line, which functions as a reflection portion for each pixel of B, G, and R, and a counter electrode, and light emission is obtained with enhanced brightness at resonant wavelengths corresponding to the respective luminescent colors of B, G, and R.

In the light-emitting device described in Japanese Patent Laid-Open No. 2021-72282, between the reflection portions of the adjacent organic light-emitting elements, a step is formed due to the reflection portion. Such a step reduces the thickness of the organic layer and reduces the distance between a first electrode (anode) and a second electrode (cathode), thereby generating a leakage current that leads to lower luminous efficiency of the organic light-emitting element. Furthermore, since an insulating layer needs to be formed highly accurately as an optical adjustment layer on the upper layer of the step, planarization by using chemical mechanical polishing (CMP) or the like is not suitable.

### SUMMARY

The technique of the present disclosure has been made in view of the above circumstances. An object of the present disclosure is to secure the thickness of the organic layer of a light-emitting device thereby reducing a leakage current between a first electrode (anode) and a second electrode (cathode).

In order to achieve the above object, a light-emitting device according to the present disclosure includes a first element and a second element on a substrate, wherein each of the first element and the second element includes a reflection portion, a first insulating layer, a first electrode, an organic layer including a luminescent layer, and a second electrode in this order from the substrate side, the first insulating layer has a depressed portion between the reflection portion of the first element and the reflection portion of the second element, and a conductor is disposed in the depressed portion. In addition, a light-emitting device according to the present disclosure includes a first element and a second element on a substrate, wherein each of the first element and the second element includes a reflection portion, a first insulating layer, a first electrode, an organic layer including a luminescent layer, and a second electrode in this order from the substrate side, the first insulating layer has a depressed portion between the reflection portion of the first element and the reflection portion of the second element, and a third insulating layer is disposed in a region overlapping the depressed portion in a plan view of the substrate. In addition, a light-emitting device according to the present disclosure includes a first element and a second element on a substrate, wherein each of the first element and the second element includes a reflection portion, a first insulating layer, a first electrode, an organic layer including a luminescent layer, and a second electrode in this order from the substrate side, a connection portion electrically connected to the first electrode is disposed between the reflection portion of the first element and the reflection portion of the second element, and a depressed portion is formed on the first electrode.

Further, in order to achieve the above object, a method for manufacturing a light-emitting device, the method includes the steps of: forming a reflection portion of a first element and a reflection portion of a second element on a substrate; forming a first insulating layer of the first element and a second insulating layer of the second element, and forming the first insulating layer of the first element or the second insulating layer of the second element between the reflection portion of the first element and the reflection portion of the second element; forming a first electrode of the first element and a first electrode of the second element; and forming a conductor on the first insulating layer of the first element or the first insulating layer of the second element between the reflection portion of the first element and the reflection portion of the second element.

Features of the present disclosure will become apparent from the following description of embodiments with reference to the attached drawings. The following description of embodiments is described by way of example.

### BRIEF DESCRIPTION OF THE DRAWINGS

FIG. 1 is a cross-sectional view showing an example of a light-emitting device according to a first embodiment.

FIG. 2 is a plan view showing an example of the light-emitting device according to the first embodiment.

FIG. 3A shows the manufacturing process of an example of the light-emitting device according to the first embodiment.

FIG. 3B shows the manufacturing process of the light-emitting device after FIG. 3A.

FIG. 3C shows the manufacturing process of the light-emitting device after FIG. 3B.

FIG. 3D shows the manufacturing process of the light-emitting device after FIG. 3C.

FIG. 3E shows the manufacturing process of the light-emitting device after FIG. 3D.

FIG. 3F shows the manufacturing process of the light-emitting device after FIG. 3E.

FIG. 3G shows the manufacturing process of the light-emitting device after FIG. 3F.

FIG. 3H shows the manufacturing process of the light-emitting device after FIG. 3G.

FIG. 3I shows the manufacturing process of the light-emitting device after FIG. 3H.

FIG. 4 is a cross-sectional view showing an example of a light-emitting device according to a second embodiment.

FIG. 5 is a plan view showing the example of the light-emitting device according to the second embodiment.

FIG. 6 is a cross-sectional view showing an example of a light-emitting device according to a third embodiment.

FIG. 7 is a cross-sectional view showing an example of a light-emitting device according to a fourth embodiment.

FIG. 8 is a plan view showing the example of the light-emitting device according to the fourth embodiment.

FIG. 9 is a cross-sectional view showing an example of a light-emitting device according to a fifth embodiment.

FIG. 10 is a cross-sectional view showing an example of a light-emitting device according to a sixth embodiment.

FIGS. 11A and 11B are plan views showing examples of the light-emitting device according to the sixth embodiment.

FIG. 12 is a cross-sectional view showing an example of a light-emitting device according to a seventh embodiment.

FIG. 13 is a cross-sectional view showing an example of a light-emitting device according to an eighth embodiment.

FIG. 14 is a plan view showing the example of the light-emitting device according to the eighth embodiment.

FIGS. 15A to 15C are cross-sectional views illustrating examples of a light-emitting device according to a ninth embodiment.

FIG. 16 is a plan view showing an example of the light-emitting device according to the ninth embodiment.

FIG. 17 shows an example of a display device according to the embodiment.

FIGS. 18A and 18B show examples of an imaging device and an electronic device according to the embodiment.

FIGS. 19A and 19B show examples of the display device according to the embodiment.

FIGS. 20A and 20B show examples of an illuminating device and an automobile provided with a lighting fixture according to the embodiment.

FIGS. 21A and 21B show examples of a wearable device according to the embodiment.

### DESCRIPTION OF THE EMBODIMENTS

Below, the embodiments of the present disclosure will be described with reference to the drawings. Note that the present disclosure is not limited to the following embodiments, and may be changed as appropriate within the scope not departing from the gist thereof. In the drawings described below, those having the same function are given the same reference numerals and signs, and description thereof may be omitted or simplified.

### First Embodiment

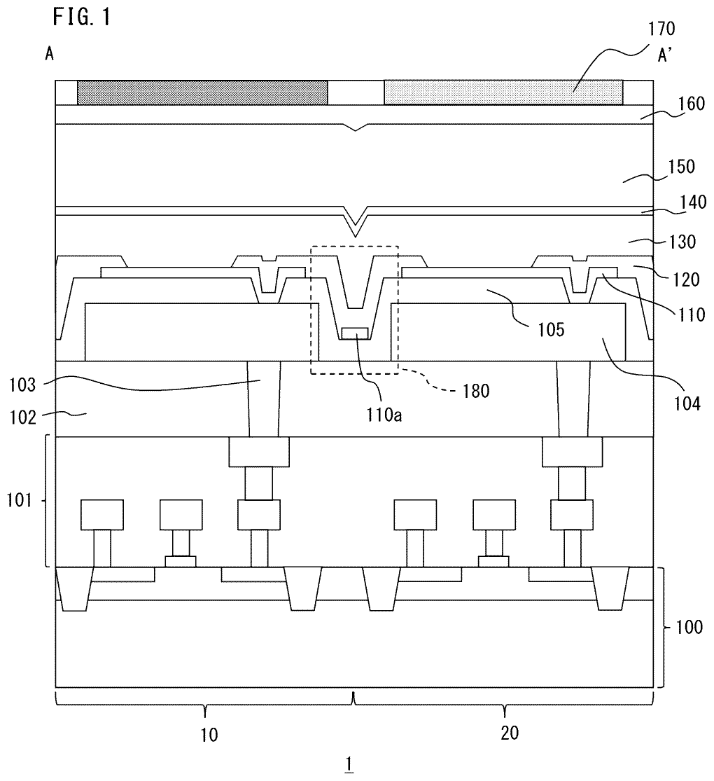

FIG. 1 is a schematic cross-sectional view of a light-emitting device 1 according to a first embodiment. As shown in FIG. 1, a wiring layer (drive circuit layer) 101 is provided on the upper side of a substrate 100 in the first direction of a substrate 100, and a first planarization layer 102 is provided on the wiring layer 101. A plurality of organic light-emitting elements 10 and 20 are provided on the first planarization layer 102. The organic light-emitting elements 10 and 20 each include a reflection portion 104, a first insulating layer 105 as an optical adjustment layer, a first electrode 110 as an anode, a second insulating layer 120, an organic layer 130 including a luminescent layer, and a second electrode 140 as a cathode in this order from the substrate side. The wiring layer 101 and the reflection portion 104 are electrically connected to the wiring layer 101 via a first conductive plug 103. The organic light-emitting element 10 is an example of a first element, and the organic light-emitting element 20 is an example of a second element.

A part of the reflection portion 104 and a part of the first electrode 110 are electrically connected to each other. The organic layer 130 includes a luminescent layer, and the luminescent layer is shared by the plurality of organic light-emitting elements 10 and 20. The organic layer 130 further includes at least an organic luminescent material layer. Furthermore, the organic layer 130 may include, for example, a charge transport layer, a charge injection layer, and a charge generation layer. The organic layer 130 is not patterned for each of the organic light-emitting elements 10 and 20 but is formed as a common layer for the plurality of organic light-emitting elements 10 and 20.

Moreover, the first insulating layer 105 is disposed to cover the reflection portion 104. The first insulating layer 105 is interposed between the reflection portions 104, and the first insulating layer 105 has a step portion 180 that is a depressed portion due to the thickness of the reflection portion 104. A conductor 110a made of the same material as the first electrode 110 is disposed on the upper side of the first insulating layer 105 and between the adjacent reflection portions 104. In the step portion 180 formed between the adjacent reflection portions 104, the conductor 110a is disposed on the upper side of the first insulating layer, thereby reducing the step height of the step portion 180. In addition, by reducing the step height of the step portion 180, a reduction in the thickness of the organic layer 130 can be suppressed, which can reduce a leakage current between the first electrode (anode) and the second electrode (cathode) via the charge transport layer, the charge injection layer, or the charge generation layer.

In FIG. 1, the above-described constituent elements of the organic light-emitting elements 10 and 20 are protected by a moisture-proof layer 150 provided on the second electrode 140. A second planarization layer 160 and a color filter layer 170 are disposed on the moisture-proof layer 150. A plurality of organic layers 130 may be stacked for a plurality of luminescent colors. For example, the organic layer 130 is configured to emit white light. White light emitted from the organic layer 130 of the organic light-emitting elements 10 and 20 passes through the color filter layer 170, so that the white light is split into red light, green light, or blue light and is emitted from the organic light-emitting elements 10 and 20.

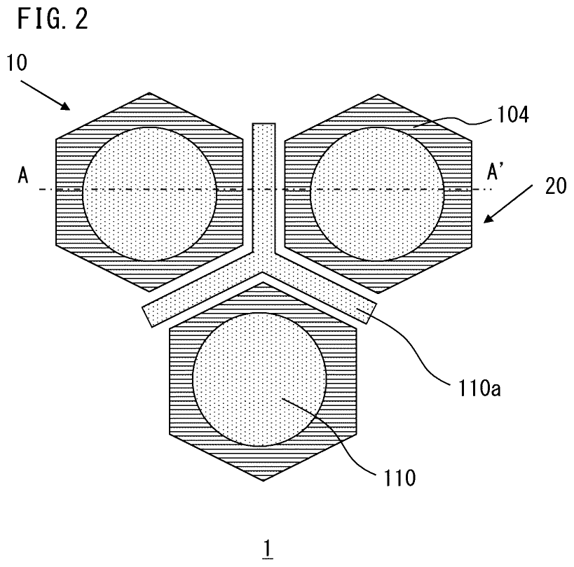

FIG. 2 shows an example of a plan view of the first electrodes 110 and the conductor 110a between the adjacent reflection portions 104 in the light-emitting device 1 according to the present embodiment. FIG. 1 is a cross-sectional schematic view of the light-emitting device 1 taken along line A-A′ of FIG. 2. The reflection portions 104 are disposed on the first planarization layer 102. The reflection portions 104 may have, for example, hexagonal shapes in a plan view of the substrate 100 but may have other polygonal shapes. The first electrode 110 is disposed on the reflection portion 104 for each of the organic light-emitting elements 10 and 20. For example, the first electrode 110 may have a circular shape in a plan view of the substrate 100 but may have a polygonal shape instead. The conductor 110a may be disposed between the adjacent reflection portions 104. The conductor 110a may be disposed only in a part of a region between the reflection portions 104 or may be disposed over a part of the reflection portion 104 in a plan view of the substrate 100. When the first electrode 110 is electrically isolated in each of the organic light-emitting elements 10 and 20, the conductor 110a and the first electrode 110 may be connected to each other.

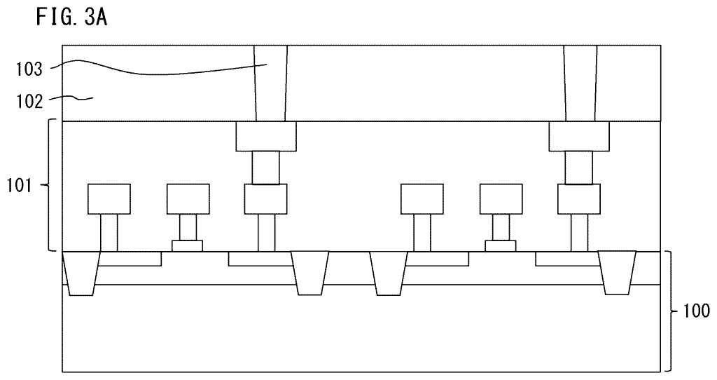

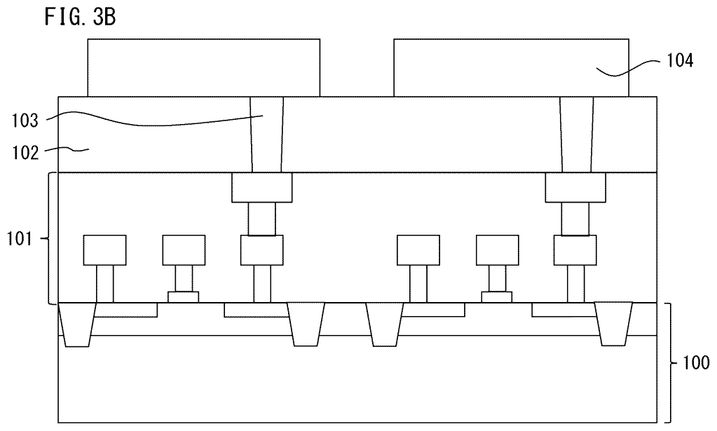

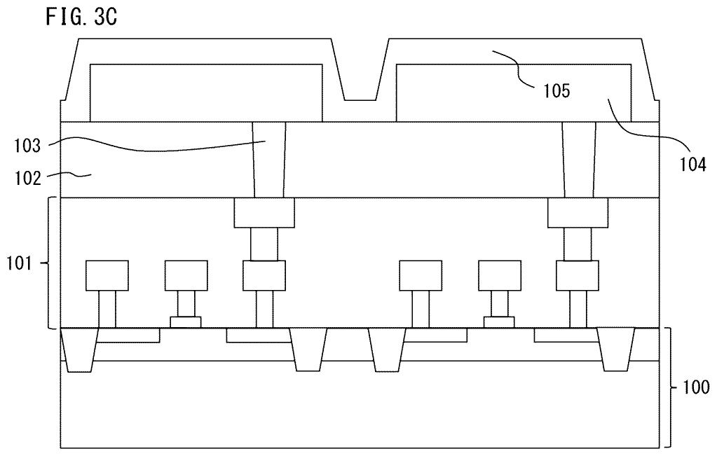

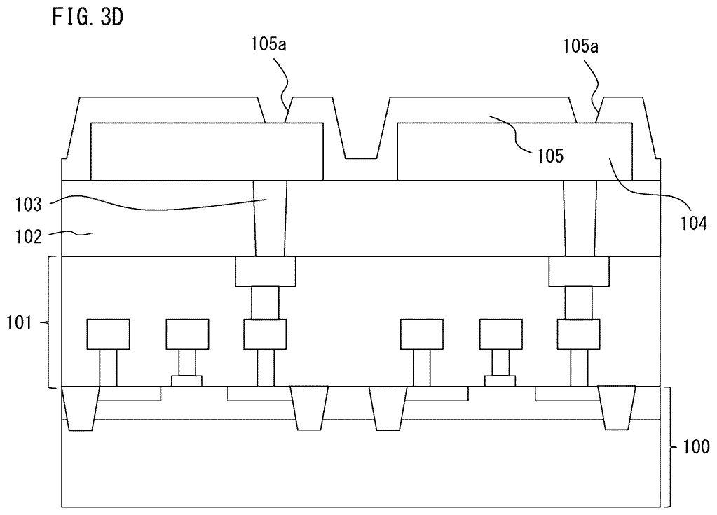

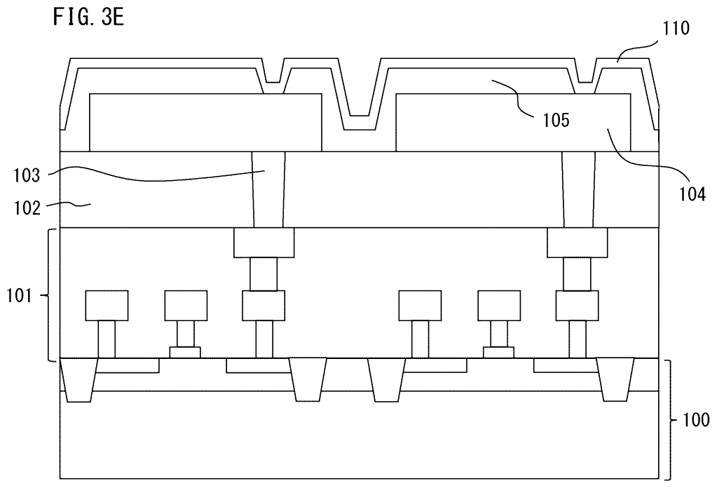

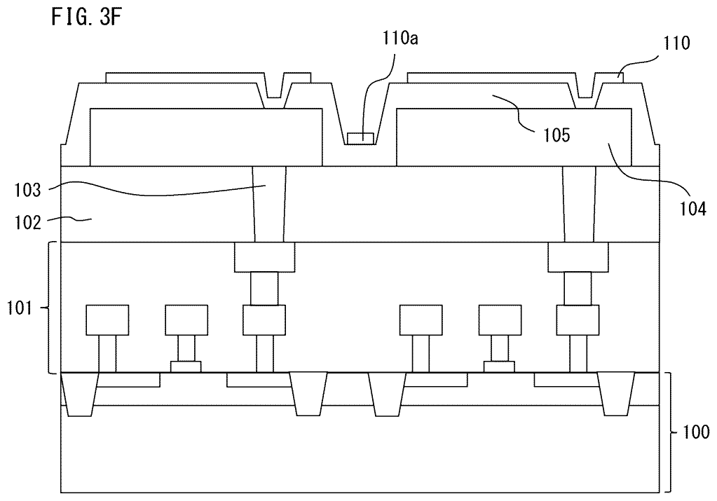

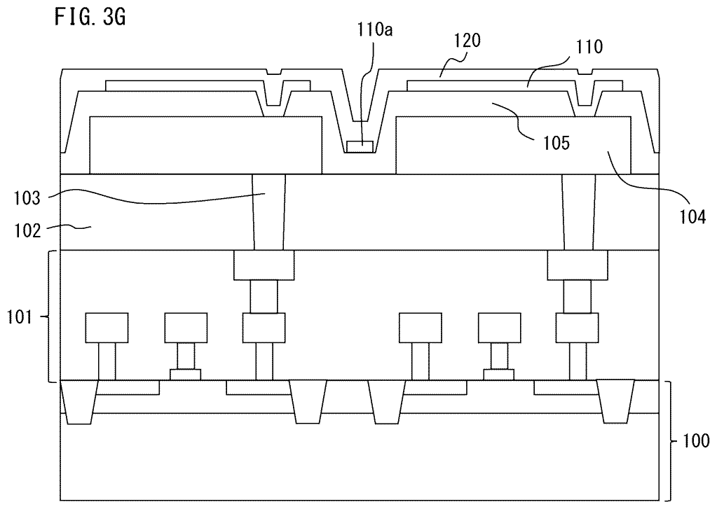

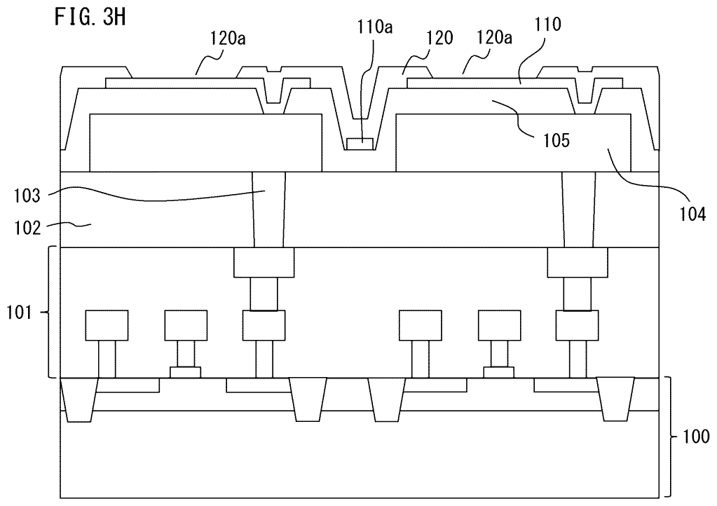

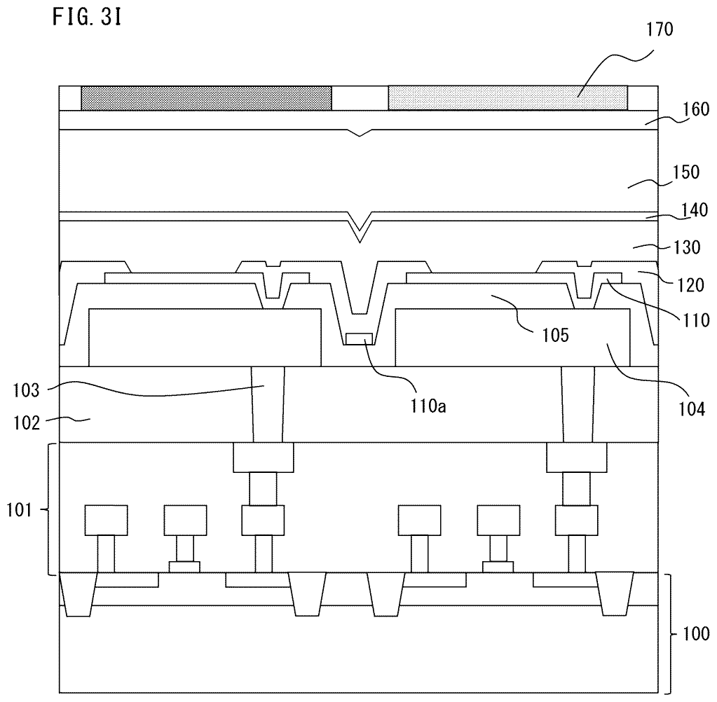

Referring to FIGS. 3A to 3I, a method for manufacturing the light-emitting device 1 of the present embodiment will be described below. First, as shown in FIG. 3A, the transistors and capacitors or the like of a drive circuit including a pixel drive circuit are arranged on the substrate 100, which is a silicon substrate doped with, for example, an impurity, according to a known MOS process, so that the wiring layer 101 is formed. Subsequently, for example, according to a plasma CVD method, a high-density plasma method, or a combination thereof, an insulating film such as an oxide film (SiOx) or an oxynitride film (SiON) is formed on the wiring layer 101, and the first planarization layer 102 is formed by planarizing the surface including a pixel region according to the CMP method.

Subsequently, in the first planarization layer 102, a plurality of openings are formed at predetermined positions by a photolithography method and a dry etching method. For example, tungsten (W) is disposed in the openings, and redundant portions are removed by the CMP method or an etch back method, so that the first conductive plugs 103 made of a conductive material (tungsten) are formed.

Thereafter, as shown in FIG. 3B, an AlCu film (for example, an Al film with 0.5 (atm %) of Cu added) is formed on the first planarization layer 102 according to, for example, a sputtering method. The AlCu film is then patterned according to the photolithography method, the dry etching method, or a wet etching method to form the plurality of reflection portions 104. Subsequently, as shown in FIG. 3C, the first insulating layer 105 composed of an SiO₂ film is formed by, for example, the plasma CVD method. In this step, in a plan view of the substrate 100, the central portion of the reflection portion 104 may be removed according to the photolithography method and the dry etching method, and the first insulating layer 105 may be stacked thereon. Thus, the thickness of the first insulating layer 105 can be adjusted according to the luminescent color in each of the organic light-emitting elements 10 and 20.

Subsequently, as shown in FIG. 3D, openings (contact holes) 105a are formed on the first insulating layer 105 according to the photolithography method and the dry etching method. Thereafter, as shown in FIG. 3E, the first electrode 110 composed of an ITO film or an IZO film is formed according to, for example, the sputtering method. As shown in FIG. 3F, the first electrode 110 is then patterned according to the photolithography method and the dry etching method, so that the plurality of first electrodes 110 are formed. In addition, the conductor 110a made of the same material as the first electrode 110 is formed between the reflection portions 104 by patterning. The formation of the conductor 110a between the reflection portions 104 can reduce the step height of the step portion 180 formed between the adjacent reflection portions 104. Furthermore, when the first electrodes 110 are formed, the first insulating layer 105 may be over-etched by the dry etching method to increase the step height between the adjacent reflection films. The formation of the conductor 110a can reduce the possibility of increasing the step height.

The method for manufacturing the light-emitting device 1 according to the present embodiment is different from the conventional method for manufacturing a light-emitting device in that the conductor 110a is formed on the first insulating layer 105 by patterning. Accordingly, according to the present embodiment, the step height can be reduced without concern about a decrease in manufacturing efficiency due to an increase in the number of steps from the conventional method for manufacturing a light-emitting device. Furthermore, by reducing the step height of the step portion 180 between the adjacent reflection portions 104, the thickness of the organic layer 130 can be secured to reduce the occurrence of leakage current between the first electrode 110 and the second electrode 140.

Subsequently, as shown in FIG. 3G, the second insulating layer 120 including a SiO₂ film or a Si₃N₄ film is formed to cover the plurality of first electrodes 110, the conductor 110a, and the first insulating layer 105 according to, for example, the plasma CVD method. The second insulating layer 120 is formed to cover the end of the first electrode 110 of the organic light-emitting element 10 and the end of the first electrode 110 of the organic light-emitting element 20 element. Thereafter, as shown in FIG. 3H, the second insulating layer 120 is patterned according to the photolithography method and the dry etching method to form openings 120a in the second insulating layer 120. Subsequently, as shown in FIG. 3I, the organic layer 130 is formed by sequentially stacking, for example, an organic layer, a luminescent layer, and an electron transport layer with a lower resistance than a luminescent layer such as a hole injection layer or a hole transport layer, as an organic material constituting the organic light-emitting element according to, for example, a vacuum deposition method. As the vacuum deposition method, for example, a rotary deposition method, a line-type deposition method, a transfer-type deposition method can be used. The organic layer 130 may include a hole injection layer, a hole transport layer, a luminescent layer, a charge generation layer, a luminescent layer, and an electron transport layer.

Thereafter, the second electrode 140 is formed according to the vacuum deposition method without releasing the substrate 100 and the layers formed on the substrate 100 from the reduced pressure atmosphere to the air. Subsequently, the moisture-proof layer 150 is formed to cover the second electrode 140 according to, for example, the plasma CVD method, the sputtering method, an ALD method, or a combination thereof. It is preferable to set the film formation temperature of the moisture-proof layer 150 to be equal to or lower than the decomposition temperature of the organic material constituting the organic layer 130, for example, 120° C. or lower. Furthermore, the second planarization layer 160 with flatness and transparency is formed on the moisture-proof layer 150. The second planarization layer 160 is then coated with, for example, a red filter material and is patterned by photolithography, so that a red filter is formed. Subsequently, a green filter and a blue filter are sequentially formed as in the formation of the red filter, so that the color filter layer 170 is formed on the second planarization layer 160. Note that the second planarization layer 160 is disposed for the purpose of improving the adhesiveness between the moisture-proof layer 150 and the color filter layer 170 and is not necessary for implementing the present embodiment. Thereafter, the terminal extraction pad portion in a display device is patterned into a predetermined shape according to the photolithography method and the dry etching method.

Furthermore, in the light-emitting device 1 of the present embodiment, the following equation (1) is satisfied, in which L is an optical path length from the top surface of the first electrode 110 to the light-emitting position of the luminescent layer in the organic layer 130.

$$L = ( 2 m - 1 ) \times ( λ / 4 ) \qquad ( 1 )$$

In the equation, m is an integer. The optical distance of the organic layer 130 can be optimized so as to satisfy the above equation (1). Here, λ may be the dominant wavelength of light emitted by the luminescent layer. For example, when the organic light-emitting element including the luminescent layer is used for a blue pixel, λ may be a blue luminous wavelength. Also, the dominant wavelength λ may be a wavelength to be extracted from the organic light-emitting element to the outside. Alternatively, the dominant wavelength λ may be the maximum peak wavelength of the luminescent material of the luminescent layer. Furthermore, if the wavelength λ satisfies the equation (1), light emitted by the luminescent layer is intensified, but the wavelength λ within the range of ±λ/8 may be used to intensify light emitted by the luminescent layer. That is, in the present embodiment, a wavelength λ that satisfies the following equation (2) may be used.

$$L = ( 2 m - 1 ) \times ( λ / 4 ) \pm λ / 8 \qquad ( 2 )$$

As described above, according to the light-emitting device 1 of the present embodiment, the thickness of the organic layer 130 can be secured to reduce a leakage current between the first electrode 110 and the second electrode 140.

### Second Embodiment

A light-emitting device according to a second embodiment will be described below. In the following description, the same configurations as those of the first embodiment are given the same reference numerals and signs, and the detailed description thereof is omitted.

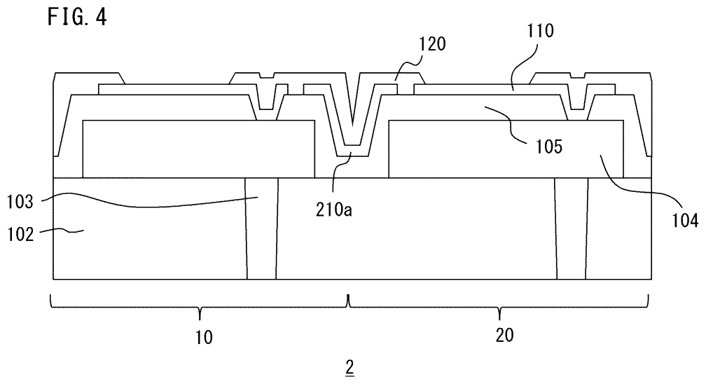

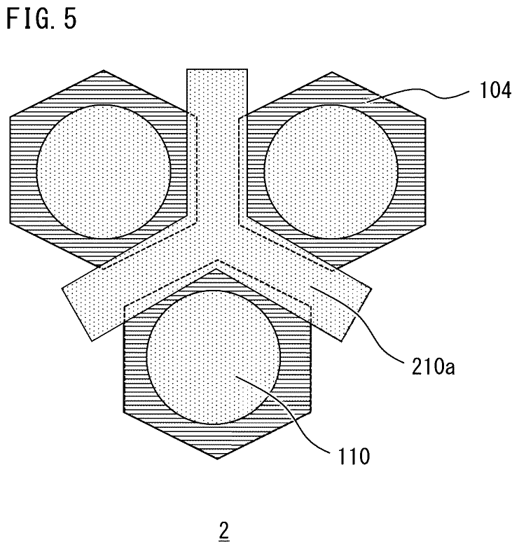

FIG. 4 is a schematic cross-sectional view of a light-emitting device 2 according to the present embodiment. In FIG. 4, a substrate 100, a wiring layer 101, an organic layer 130, a second electrode 140, a moisture-proof layer 150, a second planarization layer 160, and a color filter layer 170 of the light-emitting device 2 are not shown. FIG. 5 shows an example of a plan view of adjacent reflection portions 104, first electrodes 110, and a conductor 210a in the light-emitting device 2 according to the present embodiment. Note that in FIG. 5, other constituent elements constituting the light-emitting device 2 are the same as those of the light-emitting device 1 according to the first embodiment and thus are not shown.

In the light-emitting device 1 of the first embodiment, as shown in FIG. 2, the conductor 110a is disposed between the adjacent reflection portions 104. In contrast, in the light-emitting device 2 of the present embodiment, as shown in FIG. 5, the conductor 210a is disposed between the adjacent reflection portions 104 while overlapping the reflection portions 104 in a plan view of the substrate 100. Thus, in the method for manufacturing the light-emitting device described with reference to FIGS. 3A to 3I, the layers formed by patterning according to the photolithography method can be machined more finely in the same plane.

### Third Embodiment

A light-emitting device according to a third embodiment will be described below. In the following description, the same configurations as those of the first embodiment are given the same reference numerals and signs, and the detailed description thereof is omitted.

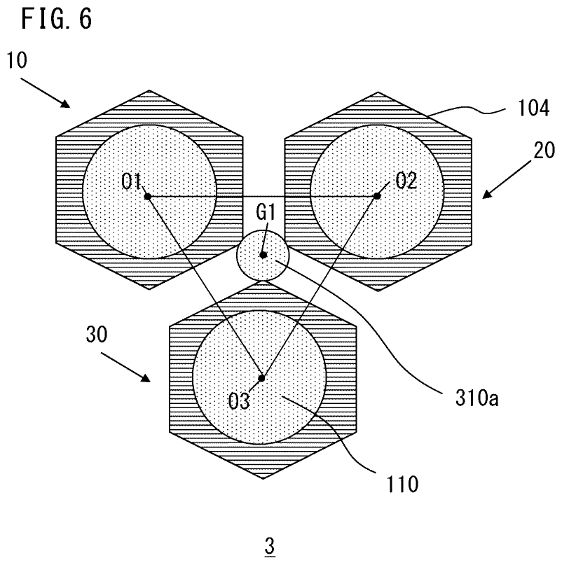

FIG. 6 shows an example of a plan view of adjacent reflection portions 104, first electrodes 110, and a conductor 310a in a light-emitting device 3 according to the present embodiment. Note that in FIG. 6, other constituent elements constituting the light-emitting device 3 are the same as those of the light-emitting device 1 according to the first embodiment and thus are not shown.

The light-emitting device 3 of the present embodiment includes organic light-emitting elements 10, 20, and 30. The organic light-emitting element 30 is a third element in which a reflection portion 104, a first insulating layer 105 as an optical adjustment layer, a first electrode 110 as an anode, a second insulating layer 120, an organic layer 130 including a luminescent layer, and a second electrode 140 as a cathode are arranged in this order from the substrate side. Furthermore, as shown in FIG. 6, the organic light-emitting elements 10, 20, and 30 are arranged such that lines connecting centers O1, O2, and O3 of the reflection portions 104 of the organic light-emitting elements 10, 20, and 30 form a triangle in a plan view of the substrate 100. Moreover, in the plan view of the substrate 100, the conductor 310a is disposed at the position of a center of gravity G1 of the triangle.

Between the adjacent reflection portions 104, a region facing the plurality of organic light-emitting elements is likely to have an area larger than other regions between the adjacent reflection portions 104, so that the region may become larger than the step height of a step portion formed between the reflection portions 104. Thus, in the present embodiment, as shown in FIG. 6, the conductor 310a faces the plurality of organic light-emitting elements between the reflection portions 104 and is formed in a region overlapping the center of gravity G1 of the triangle. Accordingly, the region overlapping the center of gravity G1 of the triangle is a region in contact with the three reflection portions 104 of the organic light-emitting elements 10, 20, and 30 and is not a region in contact with only any two of the reflection portions 104 of the organic light-emitting elements 10, 20, and 30. Since the conductor 310a is formed in such a region, in the light-emitting device 3, the step height of the step portion formed between the reflection portions 104 can be effectively reduced and a reduction of the opening of a pixel using a plurality of organic light-emitting elements can be suppressed.

### Fourth Embodiment

A light-emitting device according to a fourth embodiment will be described below. In the following description, the same configurations as those of the first embodiment are given the same reference numerals and signs, and the detailed description thereof is omitted.

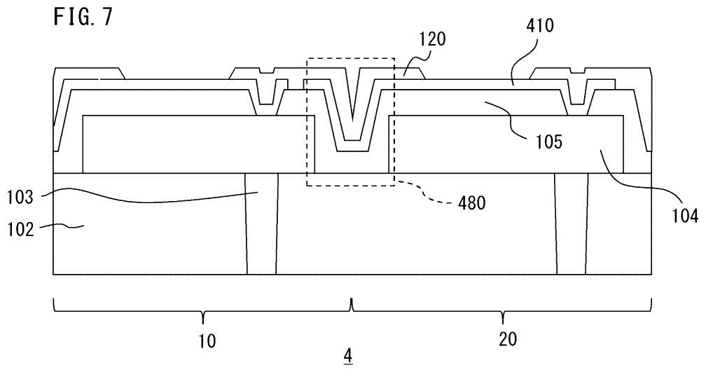

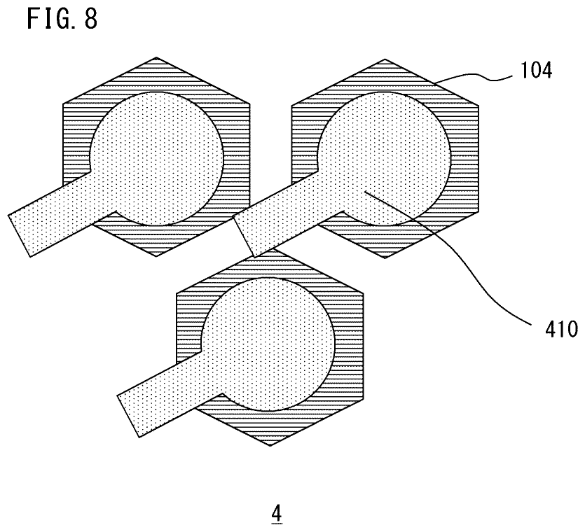

FIG. 7 is a schematic cross-sectional view of a light-emitting device 4 according to the present embodiment. In FIG. 7, a substrate 100, a wiring layer 101, an organic layer 130, a second electrode 140, a moisture-proof layer 150, a second planarization layer 160, and a color filter layer 170 of the light-emitting device 4 are not shown. FIG. 8 shows an example of a plan view of adjacent reflection portions 104 and first electrodes 410 in the light-emitting device 4 according to the present embodiment. Note that in FIG. 8, other constituent elements constituting the light-emitting device 4 are the same as those of the light-emitting device 1 according to the first embodiment and thus are not shown.

In the present embodiment, as an example, the first electrode 110 of an organic light-emitting element 20 is formed continuously between a reflection portion 104 of an organic light-emitting element 20 and the reflection portion 104 of an organic light-emitting element 10 adjacent to the organic light-emitting element 20. Patterning is performed to electrically isolate the adjacent first electrode 110 at a position between the adjacent reflection portions 104 or a position overlapping the reflection portions 104 in plan view.

FIG. 7 is a plan view showing the reflection portions 104 and parts of the first electrodes 110. The first electrode 110 covering the top where the plurality of organic light-emitting elements gather between the adjacent reflection portions 104 and the circular first electrode 110 in the reflection portion 104 are continuously formed. Meanwhile, patterning is performed to electrically isolate the adjacent first electrode 110. This eliminates the need for providing a space between the first electrode 110 and a conductor 110a as described in the third embodiment (FIG. 5). As a result, the step height of a step portion 480 formed between the reflection portions 104 can be effectively reduced, and a reduction of the opening of a pixel using the plurality of organic light-emitting elements can be suppressed.

### Fifth Embodiment

A light-emitting device according to a fifth embodiment will be described below. In the following description, the same configurations as those of the first embodiment are given the same reference numerals and signs, and the detailed description thereof is omitted.

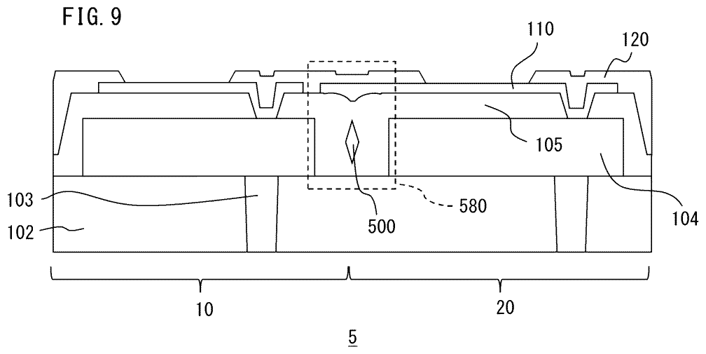

FIG. 9 is a schematic cross-sectional view of a light-emitting device 5 according to the present embodiment. In FIG. 9, a substrate 100, a wiring layer 101, an organic layer 130, a second electrode 140, a moisture-proof layer 150, a second planarization layer 160, and a color filter layer 170 of the light-emitting device 5 are not shown.

A method for manufacturing the light-emitting device 5 according to the present embodiment is manufactured using the manufacturing method described with reference to FIGS. 3A to 3I. When a first insulating layer 105 is formed in the light-emitting device 5, as shown in FIG. 9, a gap 200 is formed between adjacent reflection portions 104. In a plan view of the substrate 100, a first electrode 110 is formed in a region overlapping the gap 500, that is, in a region above the gap 500 in FIG. 9.

Thus, when the first electrode 110 is formed, the first insulating layer 105 above the gap 500 can be protected without being reduced by etching. Consequently, in the light-emitting device 5, the step height of a step portion 580 formed between the reflection portions 104 can be effectively reduced. In a plan view of the substrate 100, a conductor 110a may be formed in place of the first electrode 110 in a region overlapping the gap 500.

### Sixth Embodiment

A light-emitting device according to a sixth embodiment will be described below. In the following description, the same configurations as those of the fifth embodiment are given the same reference numerals and signs, and the detailed description thereof is omitted.

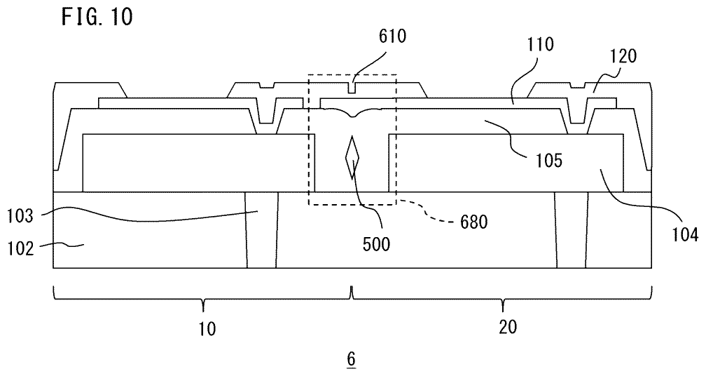

FIG. 10 is a schematic cross-sectional view of a light-emitting device 6 according to the present embodiment. In FIG. 9, a substrate 100, a wiring layer 101, an organic layer 130, a second electrode 140, a moisture-proof layer 150, a second planarization layer 160, and a color filter layer 170 of the light-emitting device 6 are not shown.

A method for manufacturing the light-emitting device 6 according to the present embodiment is manufactured using the manufacturing method described with reference to FIGS. 3A to 3I. In the light-emitting device 6, as shown in FIG. 10, a first electrode 110 is formed between adjacent reflection portions 104. Furthermore, on a second insulating layer 120, a groove 610 for reducing a leakage current between adjacent organic light-emitting elements 10 and 20 is formed according to a photolithography method and a dry etching method.

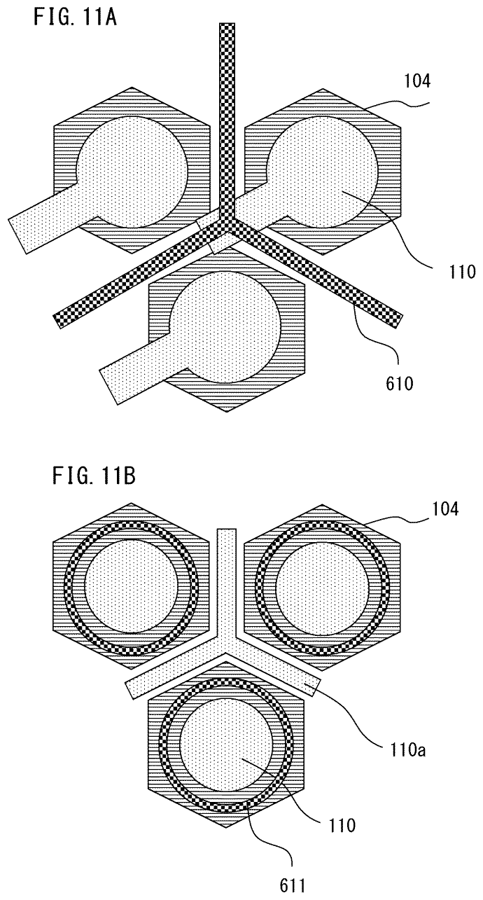

FIG. 11A shows an example of a plan view of the adjacent reflection portions 104, the first electrodes 110, and the groove 610 in the light-emitting device 6 according to the present embodiment. Note that in FIG. 11, other constituent elements constituting the light-emitting device 6 are the same as those of the light-emitting device 5 according to the fifth embodiment and thus are not shown. As shown in FIG. 11, in a plan view of the substrate 100, the groove 610 is formed in a region between the adjacent reflection portions 104 while overlapping the first electrode 110.

This can reduce the step height of a step portion between the adjacent reflection portions 104, thereby improving the workability of the groove 610, effectively reducing the step height of a step portion 680 formed between the reflection portions 104, and reducing a leakage current between the plurality of organic light-emitting elements. Furthermore, in the light-emitting device 6, the effect of suppressing a reduction of the opening of a pixel using a plurality of organic light-emitting elements can be expected.

FIG. 11B shows an example of a plan view of the adjacent reflection portions 104, the first electrodes 110, and grooves 611 in a modification example of the light-emitting device 6. Constituent elements other than the reflection portions 104, the first electrodes 110, and the grooves 611 in the present modification example are the same as those of the light-emitting device 6, and thus the illustration and description thereof are omitted. As shown in FIG. 11B, the groove 611 is formed, for example, in a region overlapping the reflection portion 104 of each of the organic light-emitting elements in the plan view of the substrate 100. In the plan view of the substrate 100, the conductor 110a may be formed in place of the first electrode 110 in a region overlapping a gap 200. Alternatively, the arrangement of the grooves may be a combination of the arrangements of FIGS. 11A and 11B. Furthermore, a groove may be formed in a region overlapping the first electrode 110 or the conductor 110a in the plan view of the substrate 100.

### Seventh Embodiment

A light-emitting device according to a sixth embodiment will be described below. In the following description, the same configurations as those of the first embodiment are given the same reference numerals and signs, and the detailed description thereof is omitted.

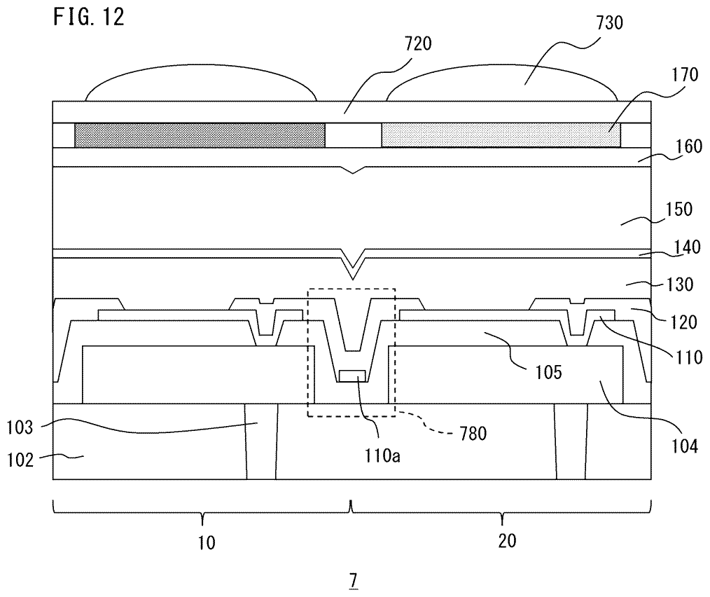

FIG. 12 is a schematic cross-sectional view of a light-emitting device 7 according to the present embodiment. In FIG. 12, a substrate 100 and a wiring layer 101 of the light-emitting device 7 are not shown.

As shown in FIG. 12, in each of organic light-emitting elements 10 and 20, a third planarization layer 720 is disposed on a color filter layer 170, and a translucent microlens 730 is disposed on the third planarization layer 720. As an example, the microlens 730 is a convex lens that is disposed in a region overlapping the color filter layer 170 in a plan view of the substrate 100 and collects nondirectional light. The microlens 730 may be a so-called spherical lens or a so-called aspherical lens. In addition, the constituent materials of the microlens 730 include materials having translucency and insulating properties. Specifically, the constituent materials of the microlens 730 include, for example, silicon-based inorganic materials such as silicon oxide and resin materials such as acrylic resin.

The light-emitting device 7 of the present embodiment can also reduce the step height of a step portion 780 between adjacent reflection portions 104 like the light-emitting device 1 of the first embodiment. This can reduce the thickness of a second planarization layer 160 and shorten the distance from an organic layer 130 including a luminescent layer to the microlens 730, thereby improving view angle characteristics in the light-emitting device 7.

### Eighth Embodiment

A light-emitting device according to an eighth embodiment will be described below. In the following description, the same configurations as those of the first embodiment are given the same reference numerals and signs, and the detailed description thereof is omitted.

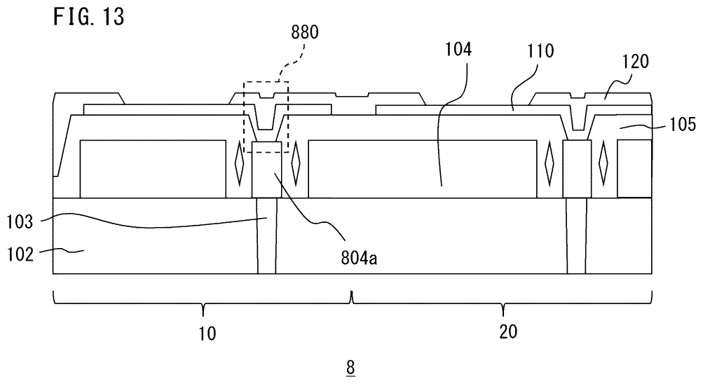

FIG. 13 is a schematic cross-sectional view of a light-emitting device 8 according to the present embodiment. In FIG. 13, a substrate 100, a wiring layer 101, an organic layer 130, a second electrode 140, a moisture-proof layer 150, a second planarization layer 160, and a color filter layer 170 of the light-emitting device 8 are not shown.

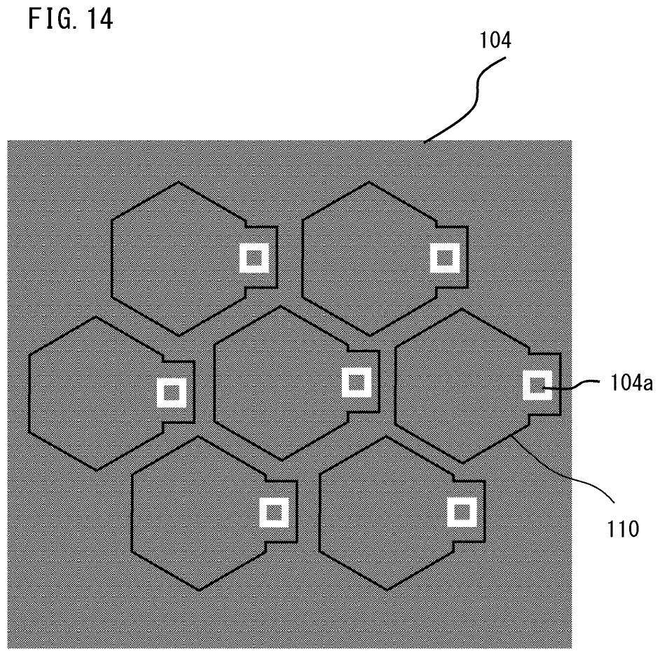

As shown in FIG. 13, in the light-emitting device 8, a wiring 804a serving as a connecting portion for connecting a first electrode 110 and a first conductive plug 103 is formed between adjacent reflection portions 104 by patterning. Furthermore, FIG. 14 shows an example of a plan view of the reflection portion 104, the first electrodes 110, and the wiring 804a in the light-emitting device 8 according to the present embodiment. Note that in FIG. 14, other constituent elements constituting the light-emitting device 8 are the same as those of the light-emitting device 1 according to the first embodiment and thus are not shown.

As shown in FIG. 14, the reflection portion 104 is provided as a common reflection portion for a plurality of organic light-emitting elements. The reflection portion 104 is not divided between the organic light-emitting elements and is arranged across a plurality of pixels in the pixel array region of the light-emitting device 8. In a plan view of the substrate 100, the first electrode 110 is formed in a region overlapping the wiring 804a, that is, in a region on the wiring 804a in FIG. 14.

Thus, the step height of a step portion 880 formed in the upper region due to the presence of the wiring 804a is reduced to secure the thickness of the organic layer 130, so that a leakage current between the first electrode 110 and the second electrode 140 can be reduced. In the plan view of the substrate 100, a conductor 110a may be formed in place of the first electrode 110 in a region overlapping the wiring 804a.

### Ninth Embodiment

A light-emitting device according to a ninth embodiment will be described below. In the following description, the same configurations as those of the first embodiment are given the same reference numerals and signs, and the detailed description thereof is omitted.

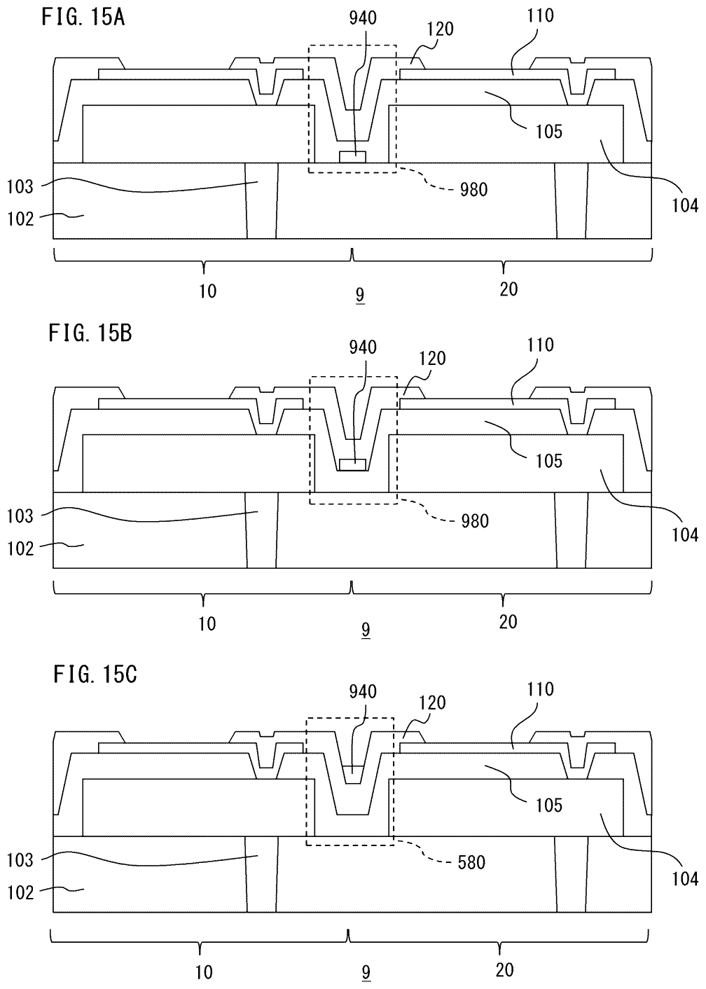

FIG. 15A is a schematic cross-sectional view of a light-emitting device 9 according to the present embodiment. In FIG. 15A, a substrate 100, a wiring layer 101, an organic layer 130, a second electrode 140, a moisture-proof layer 150, a second planarization layer 160, and a color filter layer 170 of the light-emitting device 9 are not shown.

As shown in FIG. 15A, a third insulating layer 940 is formed between adjacent reflection portions 104 in the light-emitting device 9. The third insulating layer 940 is formed by forming an insulating layer and patterning the insulating layer according to a photolithography method and a dry etching method.

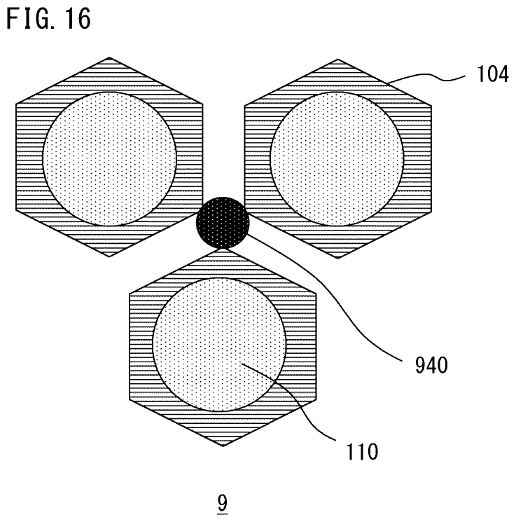

FIG. 16 is a plan view showing the reflection portions 104, the first electrodes 110, and a part of the third insulating layer 940 in the light-emitting device 9. A region facing a plurality of organic light-emitting elements is likely to have an area larger than other regions between the adjacent reflection portions 104, so that the region may become larger than the step height of a step portion formed between the reflection portions 104. Thus, in the present embodiment, as shown in FIG. 16, the third insulating layer 940 is formed in a region facing the plurality of organic light-emitting elements between the reflection portions 104. Since the third insulating layer 940 is formed thus, in the light-emitting device 9, the step height of the step portion 980 formed between the reflection portions 104 can be effectively reduced and a reduction of the opening of a pixel using a plurality of organic light-emitting elements can be suppressed.

In FIG. 15A, the third insulating layer 940 is formed on a first planarization layer 102. However, as shown in FIG. 15B, the third insulating layer 940 may be formed on the first insulating layer 105 after the first insulating layer 105 is formed (FIG. 15B), or the third insulating layer 940 may be formed on the second insulating layer 120 after the second insulating layer 120 is formed (FIG. 15C).

[Structure of an Organic Light-Emitting Element] An organic light-emitting element used for the light-emitting device of the present embodiment is provided by forming an insulating layer, a first electrode, an organic compound layer and a second electrode, on a substrate. A protective layer, a color filter, a microlens and so forth may be provided on a cathode. In a case where a color filter is provided, a planarization layer may be provided between the color filter and the protective layer. The planarization layer can be for instance made up of an acrylic resin. The same is true in a case where the planarization layer is provided between the color filter and the microlens.

[Substrate] At least one material selected from quartz, glass, silicon, resins and metals can be used as the material for the substrate that makes up the organic light-emitting element. Switching elements such as transistors and wiring may be provided on the substrate, and an insulating layer may be provided on the foregoing. Any material can be used as the insulating layer so long as a contact hole can be formed between the insulating layer and the first electrode, and insulation from unconnected wiring can be ensured, so that wiring can be formed between the first electrode and the insulating layer. For instance a resin such as a polyimide, or silicon oxide or silicon nitride can be used herein.

[Electrodes] A pair of electrodes can be used as the electrodes of the organic light-emitting element. The pair of electrodes may be an anode and a cathode. In a case where an electric field is applied in the direction in which the organic light-emitting element emits light, the electrode of higher potential is the anode, and the other electrode is the cathode. Stated otherwise, the electrode that supplies holes to the light-emitting layer is the anode, and the electrode that supplies electrons is the cathode.

A material having a work function as large as possible is preferable herein as a constituent material of the anode. For instance single metals such as gold, platinum, silver, copper, nickel, palladium, cobalt, selenium, vanadium or tungsten, and mixtures containing the foregoing metals, can be used in the anode. Alternatively, alloys obtained by combining these single metals, or metal oxides such as tin oxide, zinc oxide, indium oxide, indium tin oxide (ITO) or indium zinc oxide, may be used in the anode. Conductive polymers such as polyaniline, polypyrrole and polythiophene can also be used in the anode.

Any of the foregoing electrode materials may be used singly; alternatively, two or more materials may be used concomitantly. The anode may be made up of a single layer, or may be made up of a plurality of layers.

In a case where an electrode of the organic light-emitting element is configured in the form of a reflective electrode, the electrode material can be for instance chromium, aluminum, silver, titanium, tungsten, molybdenum, or alloys or layered bodies of the foregoing. The above materials can also function as a reflective film not having a role as an electrode. In a case where an electrode of the organic light-emitting element is configured in the form of a transparent electrode, for instance an oxide transparent conductive layer of for instance indium tin oxide (ITO) or indium zinc oxide can be used, although not particularly limited thereto, as the electrode material. The electrodes may be formed by photolithography.

A material having a small work function may be a constituent material of the cathode. For instance alkali metals such as lithium, alkaline earth metals such as calcium, single metals such as aluminum, titanium, manganese, silver, lead or chromium, and mixtures of the foregoing, may be used herein. Alternatively, alloys obtained by combining these single metals can also be used. For instance magnesium-silver, aluminum-lithium, aluminum-magnesium, silver-copper or zinc-silver can be used. Metal oxides such as indium tin oxide (ITO) can also be used. These electrode materials may be used singly as one type, or two or more types can be used concomitantly. Also, the cathode may have a single-layer structure or a multilayer structure. Silver is preferably used among the foregoing, and more preferably a silver alloy, in order to reduce silver aggregation. Any alloy ratio can be adopted, so long as silver aggregation can be reduced. A ratio silver:other metal may be for instance 1:1, or 3:1.

Although not particularly limited thereto, the cathode may be a top emission element that utilizes an oxide conductive layer of ITO or the like, or may be a bottom emission element that utilizes a reflective electrode of aluminum (Al) or the like. The method for forming the cathode is not particularly limited, but more preferably for instance a DC or AC sputtering method is resorted to, since in that case film coverage is good and resistance can be readily lowered.

[Pixel Separation Layer] The pixel separation layer of the organic light-emitting element is formed out of a silicon nitride (SiN) film, a silicon oxynitride (SiON) film, or a silicon oxide (SiO) film, in turn having been formed by chemical vapor deposition (CVD). In order to increase the in-plane resistance of the organic compound layer, preferably the thickness of the organic compound layer that is formed, particularly a hole transport layer, is set to be small at the side walls of the pixel separation layer. Specifically, the side walls can be formed to be thin by increasing vignetting at the time of deposition, through an increase of the taper angle of the side walls of the pixel separation layer and/or an increase of the thickness of the pixel separation layer.

On the other hand, it is preferable to adjust the side wall taper angle of the pixel separation layer and the thickness of the pixel separation layer so that no voids are formed in the protective layer that is formed on the pixel separation layer. The occurrence of defects in the protective layer can be reduced by virtue of the fact that no voids are formed in the protective layer. Since the occurrence of defects in the protective layer is thus reduced, it becomes possible to reduce loss of reliability for instance in terms of the occurrence of dark spots or defective conduction in the second electrode.

The present embodiment allows effectively suppressing leakage of charge to adjacent pixels even when the taper angle of the side walls of the pixel separation layer is not sharp. Studies by the inventors of the present application have revealed that leakage of charge to adjacent pixels can be sufficiently reduced if the taper angle lies in the range at least 60 degrees and not more than 90 degrees. The thickness of the pixel separation layer is preferably at least 10 nm and not more than 150 nm. A similar effect can be achieved also in a configuration having only a pixel electrode lacking a pixel separation layer. In this case, however, it is preferable to set the film thickness of the pixel electrode to be half or less the thickness the organic layer, or to impart forward taper at the ends of the pixel electrode, at a taper angle smaller than 60 degrees, since short circuits of the organic light-emitting element can be reduced thereby.

[Organic Compound Layer] The organic compound layer of the organic light-emitting element may be formed out of a single layer or multiple layers. In a case where the organic compound layer has multiple layers, these may be referred to as a hole injection layer, a hole transport layer, an electron blocking layer, a light-emitting layer, a hole blocking layer, an electron transport layer or an electron injection layer, depending on the function of the layer. The organic compound layer is mainly made up of organic compounds, but may contain inorganic atoms and inorganic compounds. For instance the organic compound layer may have copper, lithium, magnesium, aluminum, iridium, platinum, molybdenum or zinc. The organic compound layer may be disposed between the first electrode and the second electrode, and may be disposed in contact with the first electrode and the second electrode.

[Protective Layer] In the organic light-emitting element of the present embodiment, a protective layer may be provided on the second electrode. For instance, intrusion of water or the like into the organic compound layer can be reduced, and the occurrence of display defects also reduced, by bonding a glass provided with a moisture absorbent onto the second electrode. As another embodiment, a passivation film of for instance silicon nitride may be provided on the cathode, to reduce intrusion of water or the like into the organic compound layer. For instance, formation of the cathode may be followed by conveyance to another chamber, without breaking vacuum, whereupon a protective layer may be formed through formation of a silicon nitride film having a thickness of 2 μm by CVD. The protective layer may be provided by atomic deposition (ALD), after film formation by CVD. The material of the film formed by ALD is not limited, but may be for instance silicon nitride, silicon oxide or aluminum oxide. Silicon nitride may be further formed, by CVD, on the film having been formed by ALD. The film formed by ALD may be thinner than the film formed by CVD. Specifically, the thickness of the film formed by ALD may be 50% or less, or 10% or less.

[Color Filter] A color filter may be provided on the protective layer of the organic light-emitting element of the present embodiment. For instance a color filter having factored therein the size of the organic light-emitting element may be provided on another substrate, followed by affixing to a substrate having the organic light-emitting element provided thereon; alternatively, a color filter may be patterned by photolithography on the protective layer illustrated above. The color filter may be made up of a polymer.

[Planarization Layer] The organic light-emitting element of the present embodiment may have a planarization layer between the color filter and the protective layer. The planarization layer is provided for the purpose of reducing underlying layer unevenness. The planarization layer may be referred to as a resin layer in a case where the purpose of the planarization layer is not limited. The planarization layer may be made up of an organic compound, which may be a low-molecular or high-molecular compound, preferably a high-molecular compound.

The planarization layer may be provided above and below the color filter, and the constituent materials of the respective planarization layers may be identical or dissimilar. Concrete examples include polyvinylcarbazole resins, polycarbonate resins, polyester resins, ABS resins, acrylic resins, polyimide resins, phenolic resins, epoxy resins, silicone resins and urea resins.

[Microlens] The organic light-emitting element may have an optical member such as a microlens, on the light exit side. The microlens may be made up of for instance an acrylic resin or an epoxy resin. The purpose of the microlens may be to increase the amount of light extracted from the organic light-emitting element, and to control the direction of the extracted light. The microlens may have a hemispherical shape. In a case where the microlens has a hemispherical shape, then from among tangent lines that are in contact with the hemisphere there is a tangent line that is parallel to the insulating layer, such that the point of contact between that tangent line and the hemisphere is the apex of the microlens. The apex of the microlens can be established similarly in any cross section. That is, among tangent lines that are in contact with a semicircle of the microlens in a sectional view, there is a tangent line that is parallel to the insulating layer, such that the point of contact between that tangent line and the semicircle is the apex of the microlens.

A midpoint of the microlens can also be defined. Given a hypothetical line segment from the end point of an arc shape to the end point of another arc shape, in a cross section of the microlens, the midpoint of that line segment can be referred to as the midpoint of the microlens. The cross section for discriminating the apex and the midpoint may be a cross section that is perpendicular to the insulating layer.

The microlens has a first surface with a convex portion and a second surface on the reverse side from that of the first surface. Preferably, the second surface is disposed closer to a functional layer than the first surface. In adopting such a configuration, the microlens must be formed the organic light-emitting element. In a case where the functional layer is an organic layer, it is preferable to avoid high-temperature processes in the manufacturing process. If a configuration is adopted in which the second surface is disposed closer to the functional layer than the first surface, the glass transition temperatures of all the organic compounds that make up the organic layer are preferably 100° C. or higher, and more preferably 130° C. or higher.

[Counter Substrate] The organic light-emitting element of the present embodiment may have a counter substrate on the planarization layer. The counter substrate is so called because it is provided at a position corresponding to the above-described substrate. The constituent material of the counter substrate may be the same as that of the substrate described above. The counter substrate can be used as the second substrate in a case where the substrate described above is used as the first substrate.

[Organic Layer] Each organic compound layer (hole injection layer, hole transport layer, electron blocking layer, light-emitting layer, hole blocking layer, electron transport layer, electron injection layer and so forth) that makes up the organic light-emitting element of the present embodiment is formed in accordance with one of the methods illustrated below.

A dry process such as vacuum deposition, ionization deposition, sputtering, plasma or the like can be used for the organic compound layers that make up the organic light-emitting element of the present embodiment. A wet process in which a layer is formed through dissolution in an appropriate solvent, relying on a known coating method (for instance spin coating, dipping, casting, LB film deposition to inkjet) can resorted to instead of a dry process.

When a layer is formed for instance by vacuum deposition or by solution coating, crystallization or the like is unlikelier occur; this translates into superior stability over time. In a case where a film is formed in accordance with a coating method, the film can be formed by being combined with an appropriate binder resin.

Examples of binder resins include, although not limited to, polyvinylcarbazole resins, polycarbonate resins, polyester resins, ABS resins, acrylic resins, polyimide resins, phenolic resins, epoxy resins, silicone resins and urea resins. These binder resins may be used singly as one type, in the form of homopolymers or copolymers; alternatively, two or more types of binder resin may be used in the form of mixtures. Additives such as known plasticizers, antioxidants and ultraviolet absorbers may be further used concomitantly, as needed.

[Pixel Circuit] A light-emitting device having the organic light-emitting element of the present embodiment may have pixel circuits connected to respective organic light-emitting elements. The pixel circuits may be of active matrix type, and may control independently emission of light by the first organic light-emitting element and the second organic light-emitting element. Active matrix circuits may be voltage-programmed or current-programmed. A drive circuit has a pixel circuit for each pixel. Each pixel circuit may have an organic light-emitting element, a transistor that controls the emission luminance of the organic light-emitting element, a transistor that controls emission timing, a capacitor which holds the gate voltage of the transistor that controls emission luminance, and a transistor for connection to GND bypassing the light-emitting element.

The light-emitting device has a display area and a peripheral area disposed around the display area. The display area has pixel circuits, and the peripheral area has a display control circuit. The mobility of the transistors that make up the pixel circuits may be lower than the mobility of the transistors that make up the display control circuit. The slope of the current-voltage characteristic of the transistors that make up the pixel circuits may be gentler than the slope of the current-voltage characteristic of the transistors that make up the display control circuit. The slope of the current-voltage characteristics can be measured on the basis of a so-called Vg-Ig characteristic. The transistors that make up the pixel circuits are connected to light-emitting elements such as the first organic light-emitting element.

[Pixels] The organic light-emitting element of the present embodiment has a plurality of pixels. The pixels have sub-pixels that emit mutually different colors. The sub-pixels may have for instance respective RGB emission colors. The pixels emit light in a pixel opening region. This region is the same as the first region. The aperture diameter of the pixel openings may be 15 μm or smaller, and may be 5 μm or larger. More specifically, the aperture diameter of the pixel openings may be for instance 11 μm, or 9.5 μm, or 7.4 μm, or 6.4 μm. The spacing between sub-pixels may be 10 μm or smaller, specifically 8 μm, or 7.4 μm, or 6.4 μm.

The pixels can have any known arrangement in a plan view. For instance, the pixel layout may be a stripe arrangement, a delta arrangement, a penile arrangement or a Bayer arrangement. The shape of the sub-pixels in a plan view may be any known shape. For instance, the sub-pixel shape may be for instance quadrangular, such as rectangular or rhomboidal, or may be hexagonal. Needless to say, the shape of the sub-pixels is not an exact shape, and a shape close to that a of rectangle falls under a rectangular shape. Sub-pixel shapes and pixel arrays can be combined with each other.

[Use of the Organic Light-Emitting Element] The organic light-emitting element according to the present embodiment can be used as a constituent member of a display device or of a lighting device. Other uses of the organic light-emitting element include exposure light sources for electrophotographic image forming apparatuses, backlights for liquid crystal display devices, and light-emitting devices having color filters, in white light sources.

The display device may be an image information processing device having an image input unit for input of image information, for instance from an area CCD, a linear CCD or a memory card, and an information processing unit for processing inputted information, such that an inputted image is displayed on a display unit.

A display unit of an imaging device or of an inkjet printer may have a touch panel function. The driving scheme of this touch panel function may be an infrared scheme, a capacitive scheme, a resistive film scheme or an electromagnetic induction scheme, and is not particularly limited. The display device may also be used in a display unit of a multi-function printer.

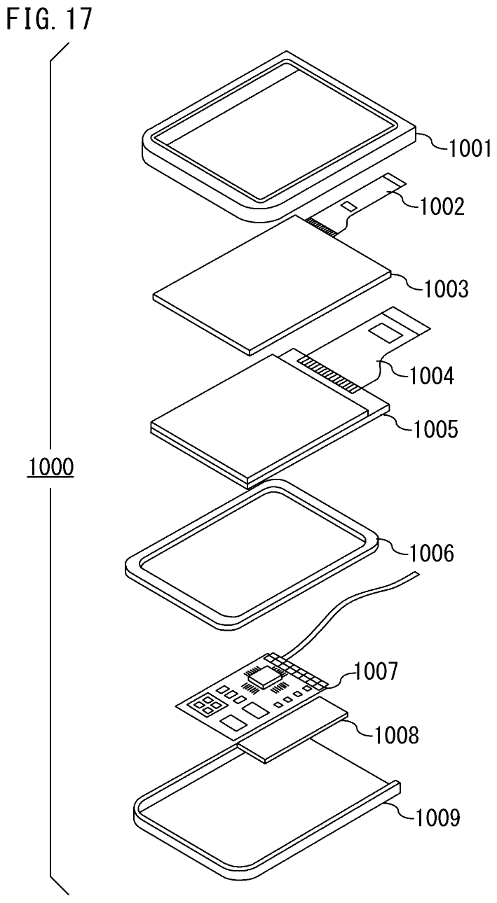

FIG. 17 illustrates a schematic diagram depicting an example of a display device having a light-emitting device according to one of the above embodiments. A display device 1000 may have a touch panel 1003, a display panel 1005, a frame 1006, a circuit board 1007 and a battery 1008, between an upper cover 1001 and a lower cover 1009. The touch panel 1003 and the display panel 1005 are connected to flexible printed circuits FPCs 1002, 1004. Transistors are printed on the circuit board 1007. The battery 1008 may be omitted if the display device is not a portable device; even if the display device is a portable device, the battery 1008 may be provided at a different position.

The display device 1000 may have red, green and blue color filters. The color filters may be disposed in a delta arrangement of the above red, green and blue. The display device 1000 may be used as a display unit of a mobile terminal. In that case the display device 1000 may have both a display function and an operation function. Mobile terminals include mobile phones such as smartphones, tablets and head-mounted displays.

The display device 1000 may be used in a display unit of an imaging device that has an optical unit having a plurality of lenses, and that has an imaging element which receives light having passed through the optical unit. The imaging device may have a display unit that displays information acquired by the imaging element. The display unit may be a display unit exposed outside the imaging device, or may be a display unit disposed within a viewfinder. The imaging device may be a digital camera or a digital video camera.

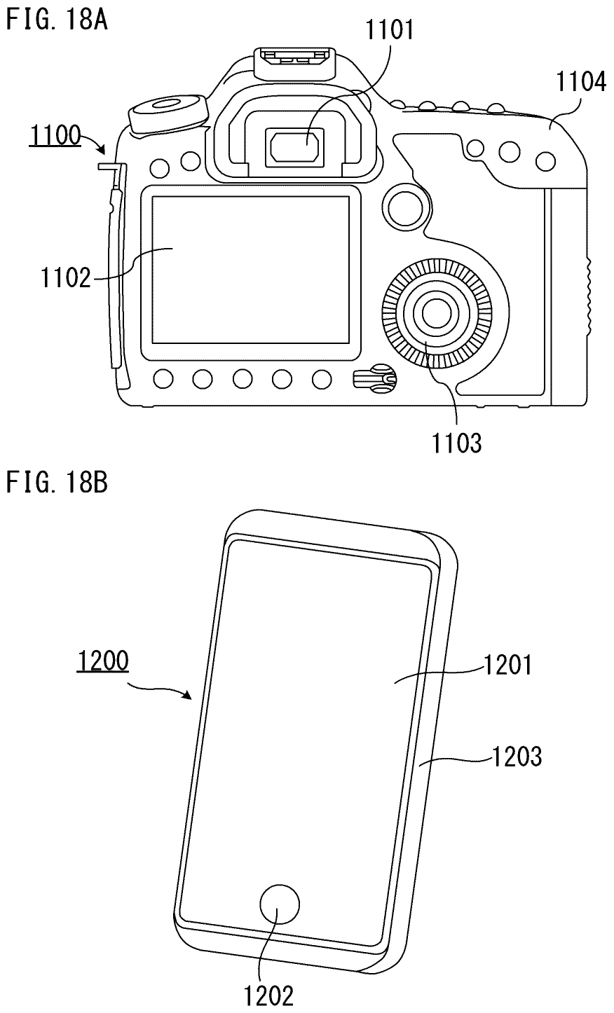

Next, FIG. 18A illustrates a schematic diagram depicting an example of an imaging device having a light-emitting device according to one of the above embodiments. An imaging device 1100 may have a viewfinder 1101, a rear display 1102, an operation unit 1103 and a housing 1104. The viewfinder 1101 may have the display device according to the present embodiment. In that case the display device may display not only an image to be captured, but also for instance environment information and imaging instructions. The environment information may include for instance external light intensity, external light orientation, the moving speed of a subject, and the chance of the subject being blocked by an obstacle.

The timing suitable for imaging is short, and hence information should be displayed as soon as possible. It is therefore preferable to configure the display device so as to have high response speed, using the organic light-emitting element of the present embodiment. A display device that utilizes the organic light-emitting element can be utilized more suitably than these devices or liquid crystal display devices, where high display speed is required.

The imaging device 1100 has an optical unit, not shown. The optical unit has a plurality of lenses, and forms an image on an imaging element accommodated in the housing 1104. The lenses can be focused through adjustment of the relative positions thereof. This operation can also be performed automatically. The imaging device may be referred to as a photoelectric conversion device. The photoelectric conversion device can encompass, as an imaging method other than sequential imaging, a method that involves detecting a difference relative to a previous image, and a method that involves cutting out part of a recorded image.

FIG. 18B is a schematic diagram illustrating an example of an electronic device having a light-emitting device according to one of the above embodiments. An electronic device 1200 includes a display unit 1201, an operation unit 1202, and a housing 1203. The housing 1203 may have a circuit, a printed board having the circuit, a battery, and a communication unit. The operation unit 1202 may be a button, or a touch panel-type reaction unit. The operation unit may be a biometric recognition unit which for instance performs unlocking upon recognition of a fingerprint. The electronic device having a communication unit can also be referred to as a communication device. The electronic device 1200 may further have a camera function, by being provided with a lens and an imaging element. Images captured by way of the camera function are displayed on the display unit. Examples of the electronic device include smartphones and notebook computers.

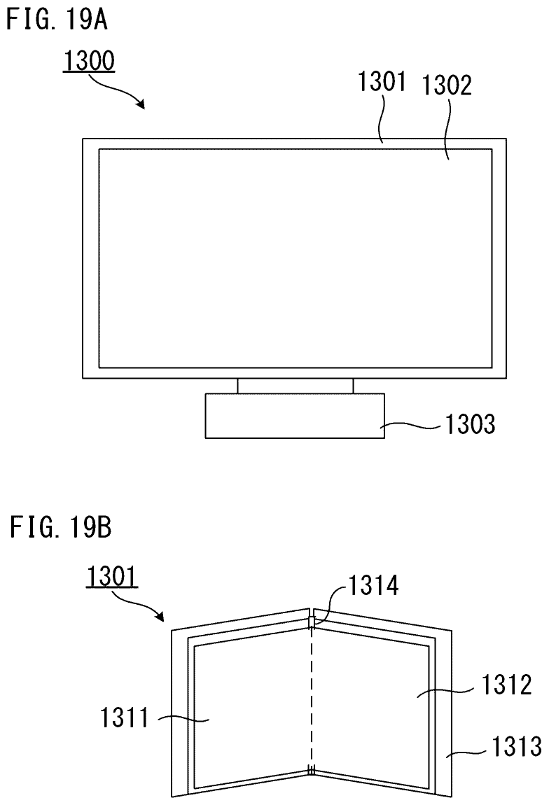

Next, FIG. 19A illustrates a schematic diagram depicting an example of a display device having a light-emitting device according to one of the above embodiments. FIG. 19A illustrates a display device 1300 such as a television monitor or PC monitor. The display device 1300 has a frame 1301 and a display unit 1302. The display unit 1302 may use the organic light-emitting element according to the present embodiment. The display device 1300 also has the frame 1301 and a base 1303 that supports the display unit 1302. The form of the base 1303 is not limited to the form in FIG. 19A. The lower side of the frame 1301 may also double as the base. The frame 1301 and the display unit 1302 may be curved. The radius of curvature of the foregoing may be at least 5000 mm and not more than 6000 mm.

FIG. 19B is a schematic diagram illustrating another example of a display device having the organic light-emitting element according to the present embodiment. A display device 1310 in FIG. 19B is a so-called foldable display device, configured to be foldable. The display device 1310 has a first display unit 1311, a second display unit 1312, a housing 1313 and a folding point 1314. The first display unit 1311 and the second display unit 1312 may have the organic light-emitting element according to the present embodiment. The first display unit 1311 and the second display unit 1312 may be one seamless display device. The first display unit 1311 and the second display unit 1312 can be separated at the folding point. The first display unit 1311 and the second display unit 1312 may display different images; alternatively, the first display unit and the second display unit may display one image.

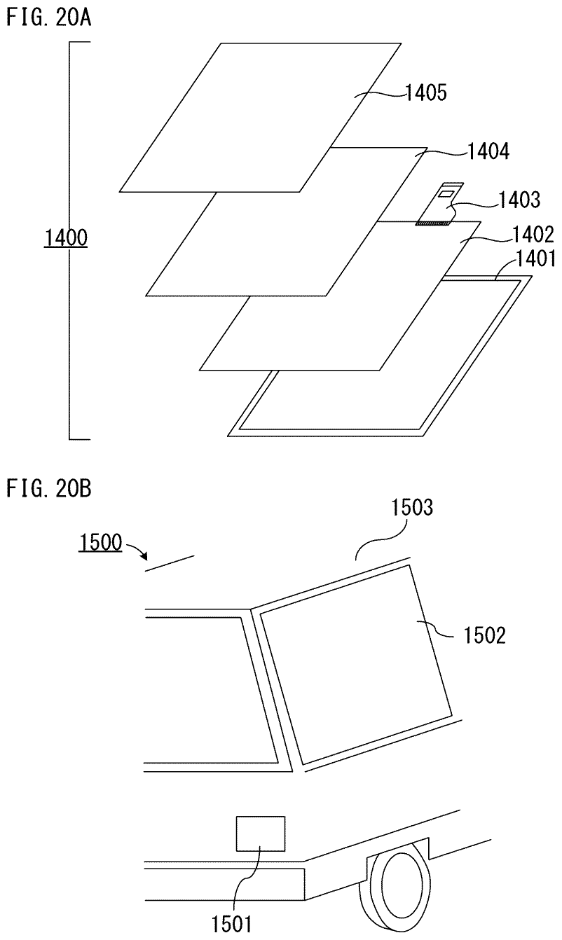

FIG. 20A illustrates next a schematic diagram depicting an example of a lighting device having a light-emitting device according to one of the above embodiments. A lighting device 1400 may have a housing 1401, a light source 1402, a circuit board 1403, an optical film 1404 and a light-diffusing part 1405. The light source has the organic light-emitting element according to the present embodiment. The optical film may be a filter that enhances the color rendering of the light source. The light-diffusing part allows effectively diffusing light from the light source, and allows delivering light over a wide area, for instance in exterior decorative lighting. The optical filter and the light-diffusing part may be provided on the light exit side of the lighting device. A cover may be provided on the outermost part, as the case may require.

The lighting device 1400 is for instance a device for indoor illumination. The lighting device may emit white, daylight white, or other colors from blue to red. The lighting device may have a light control circuit for controlling light having the foregoing emission colors. The lighting device 1400 may have the organic light-emitting element according to the present embodiment, and a power supply circuit connected thereto. The power supply circuit is a circuit that converts AC voltage to DC voltage. White denotes herein a color with a color temperature of 4200 K, and daylight white denotes a color with a color temperature of 5000 K. The lighting device 1400 may have a color filter. The lighting device 1400 may have a heat dissipation part. The heat dissipation part dumps, out of the device, heat from inside the device; the heat dissipation part may be made up of a metal or of liquid silicone rubber, exhibiting high specific heat.

FIG. 20B is a schematic diagram of an automobile, which is an example of a moving body having a light-emitting device according to one of the above embodiments. The automobile has tail lamps, being an example of a lamp. The automobile 1500 may have a tail lamp 1501, of a form such that the tail lamp is lit up when for instance a braking operation is performed.

The tail lamp 1501 has the organic light-emitting element according to the present embodiment. The tail lamp may have a protective member that protects the organic light-emitting element. The protective member may be made up of any material, so long as the material has a certain degree of high strength and is transparent; the protective member is preferably made up of polycarbonate or the like. For instance a furandicarboxylic acid derivative or an acrylonitrile derivative may be mixed with the polycarbonate.

The automobile 1500 may have a vehicle body 1503, and a window 1502 attached to the vehicle body 1503. The window may be a transparent display, unless the purpose of the window is to look ahead and behind the automobile. The transparent display may have the organic light-emitting element according to the present embodiment. In that case, constituent materials such as the electrodes of the organic light-emitting element are made up of transparent members.

The moving body having the light-emitting device according to one of the above embodiments may be for instance a vessel, an aircraft or a drone. The moving body may have a body frame and a lamp provided on the body frame. The lamp may emit light for indicating the position of the body frame. The lamp has the organic light-emitting element according to the above embodiment.

Also, the display device having the light-emitting device according to one of the above embodiments can be used in a system that can be worn as a wearable device, such as smart glasses, HMDs or smart contacts. An imaging display device used in such an application example may have an imaging device capable of photoelectrically converting visible light, and a display device capable of emitting visible light.

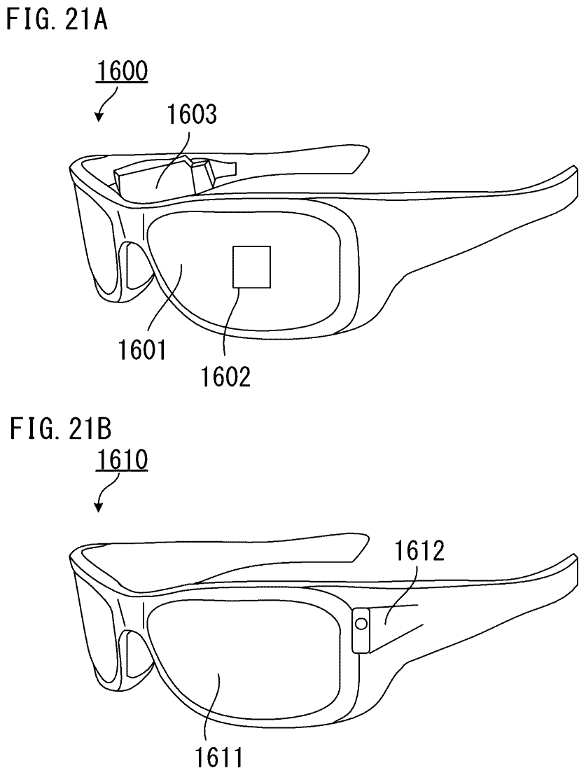

FIG. 21A illustrates spectacles 1600 (smart glasses) according to an application example of the display device having a light-emitting device according to one of the above embodiments. An imaging device 1602 such as a CMOS sensor or a SPAD is provided on the front surface side of a lens 1601 of the spectacles 1600. A display device of the embodiments described above is provided on the back surface side of the lens 1601.

The spectacles 1600 further have a control device 1603. The control device 1603 functions as a power supply that supplies power to the imaging device 1602 and to the display device according to the embodiments. The control device 1603 controls the operations of the imaging device 1602 and of the display device. The lens 1601 has formed therein an optical system for condensing light onto the imaging device 1602.

FIG. 21B illustrates spectacles 1610 (smart glasses) according to another application example of the display device having a light-emitting device according to one of the above embodiments. The spectacles 1610 have a control device 1612. The control device 1612 has mounted therein an imaging device corresponding to the imaging device 1602, and a display device. In a lens 1611 there is formed an optical system for projecting the light emitted by the display device in the control device 1612, such that an image is projected onto the lens 1611. The control device 1612 functions as a power supply that supplies power to the imaging device and to the display device, and controls the operations of the imaging device and of the display device. The control device may have a line-of-sight detection unit that detects the line of sight of the wearer. Infrared rays may be used herein for line-of-sight detection. An infrared light-emitting unit emits infrared light towards one eyeball of a user who is gazing at a display image. The infrared light emitted is reflected by the eyeball, and is detected by an imaging unit having a light-receiving element, whereby a captured image of the eyeball is obtained as a result. Impairment of the appearance of the image is reduced herein by having a reducing means for reducing light from the infrared light-emitting unit to the display unit, in a plan view.

The line of sight of the user with respect to the display image is detected on the basis of the captured image of the eyeball obtained through infrared light capture. Any known method can be adopted for line-of-sight detection using the captured image of the eyeball. As an example, a line-of-sight detection method can be resorted to that utilizes Purkinje images obtained through reflection of irradiation light on the cornea.

More specifically, line-of-sight detection processing based on a pupillary-corneal reflection method is carried out herein. The line of sight of the user is detected by calculating a line-of-sight vector that represents the orientation (rotation angle) of the eyeball, on the basis of a Purkinje image and a pupil image included in the captured image of the eyeball, in accordance with a pupillary-corneal reflection method.

The display device having the light-emitting device according to one of the above embodiments may have an imaging device having a light-receiving element, and may control the display image of the display device on the basis of line-of-sight information about the user, from the imaging device.

Specifically, a first visual field area gazed at by the user and a second visual field area, other than the first visual field area, are determined in the display device on the basis of line-of-sight information. The first visual field area and the second visual field area may be determined by the control device of the display device; alternatively, the display device may receive visual field areas determined by an external control device. In a display area of the display device, the display resolution in the first visual field area may be controlled to be higher than the display resolution in the second visual field area. That is, the resolution in the second visual field area may set to be lower than that of the first visual field area.

The display area may have a first display area and a second display area different from the first display area, such that the display device selects the area of higher priority, from among the first display area and the second display area, on the basis of the line-of-sight information. The first display area and the second display area may be determined by the control device of the display device; alternatively, the display device may receive display areas determined by an external control device. The display device may control the resolution in a high-priority area so as to be higher than the resolution in areas other than high-priority areas. That is, the display device may lower the resolution in areas of relatively low priority.

Herein AI (Artificial Intelligence) may be used to determine the first visual field area and high-priority areas. The AI may be a model constructed to estimate, from an image of the eyeball, a line-of-sight angle, and the distance to an object lying ahead in the line of sight, using training data in the form of the image of the eyeball and the direction towards which the eyeball in the image was actually gazing at. An AI program may be provided in the display device, in the imaging device, or in an external device. In a case where an external device has the AI program, the AI program is transmitted to the display device via communication from the external device.

In a case where the display device performs display control on the basis of on visual recognition detection, the display device can be preferably used in smart glasses further having an imaging device that captures images of the exterior. The smart glasses can display captured external information in real time.

As described above, by using the device using the light-emitting device according to the foregoing embodiment, stable display can be provided with high image quality for a long time.

According to the technique of the present disclosure, the thickness of the organic layer of the light-emitting device can be secured thereby reducing a leakage current between the first electrode (anode) and the second electrode (cathode).

### OTHER EMBODIMENTS

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. A light-emitting device comprising:
a first element and a second element on a substrate,
wherein each of the first element and the second element includes a reflection portion, a first insulating layer, a first electrode, an organic layer including a luminescent layer, and a second electrode in this order from the substrate side,
the first insulating layer has a depressed portion between the reflection portion of the first element and the reflection portion of the second element, and
a conductor is disposed in the depressed portion.

2. The light-emitting device according to claim 1, wherein the organic layer comes into the depressed portion.

3. The light-emitting device according to claim 1, wherein the conductor is electrically isolated from the first electrode.

4. The light-emitting device according to claim 1, wherein at least a part of the conductor overlaps the reflection portion of the first element and the reflection portion of the second element in a plan view of the substrate.

5. The light-emitting device according to claim 1, further comprising:
a second insulating layer covering an end of the first electrode of the first element and an end of the first electrode of the second element,
wherein the second insulating layer has a depressed portion between the reflection portion of the first element and the reflection portion of the second element.

6. The light-emitting device according to claim 5, wherein the conductor is disposed between the first insulating layer and the second insulating layer.

7. The light-emitting device according to claim 1, further comprising:
a third element disposed on the substrate,
wherein the third element includes a reflection portion, a first insulating layer, a first electrode, an organic layer including a luminescent layer, and a second electrode in this order from the substrate side,
the third element is arranged such that a line connecting each of centers of the reflection portion of the first element, the reflection portion of the second element, and the reflection portion of the third element forms a triangle in a plan view of the substrate, and
the conductor is disposed at a position of a center of gravity of the triangle in the plan view of the substrate.

8. The light-emitting device according to claim 7, wherein in the plan view of the substrate, the conductor is not disposed in a region in contact with only any two of the reflection portion of the first element, the reflection portion of the second element, and the reflection portion of the third element.

9. The light-emitting device according to claim 1, wherein a part of the first electrode is disposed between the reflection portion of the first element and the reflection portion of the second element.

10. The light-emitting device according to claim 1, wherein the first insulating layer has a gap disposed between the reflection portion of the first element and the reflection portion of the second element.

11. The light-emitting device according to claim 1, wherein the luminescent layer generates white light, and
the first element and the second element each have a color filter that allows passage of red light, blue light, or green light of the white light.

12. The light-emitting device according to claim 1, wherein the luminescent layer generates nondirectional light, and
the first element and the second element each have a microlens that collects the nondirectional light.

13. The light-emitting device according to claim 5, wherein the second insulating layer has a groove formed between the reflection portion of the first element and the reflection portion of the second element and in a region overlapping the first electrode or the conductor in the plan view of the substrate.

14. The light-emitting device according to claim 5, wherein the second insulating layer has a groove formed in a region overlapping the reflection portion of the first element or the reflection portion of the second element in the plan view of the substrate.

15. The light-emitting device according to claim 1, wherein equation (1) is satisfied, when L is an optical path length between the first electrode and the luminescent layer,
L=(2m−1)×(λ/4)+(λ/8) . . . (1)
where λ is a dominant wavelength of light emitted by the luminescent layer, and m is an integer.

16. The light-emitting device according to claim 1, wherein the conductor is made of the same material as that of the first electrode.

17. A light-emitting device comprising:
a first element and a second element on a substrate,
wherein each of the first element and the second element includes a reflection portion, a first insulating layer, a first electrode, an organic layer including a luminescent layer, and a second electrode in this order from the substrate side,
the first insulating layer has a depressed portion between the reflection portion of the first element and the reflection portion of the second element, and
a third insulating layer is disposed in a region overlapping the depressed portion in a plan view of the substrate.

18. A light-emitting device comprising:
a first element and a second element on a substrate,
wherein each of the first element and the second element includes a reflection portion, a first insulating layer, a first electrode, an organic layer including a luminescent layer, and a second electrode in this order from the substrate side,
a connection portion electrically connected to the first electrode is disposed between the reflection portion of the first element and the reflection portion of the second element, and
a depressed portion is formed on the first electrode.

19. The light-emitting device according to claim 1, wherein the first insulating layer is an optical adjustment layer.

20. A display device comprising:
a plurality of pixels,
wherein at least one of the plurality of pixels includes the light-emitting device according to claim 1 and a transistor connected to the light-emitting device.

21. A photoelectric conversion device comprising:
an optical unit including a plurality of lenses;
an imaging element that receives light having passed through the optical unit; and
a display unit that displays an image captured by the imaging element,
wherein the display unit includes the light-emitting device according to claim 1.

22. An electronic device comprising:
a display unit including the light-emitting device according to claim 1;
a housing provided with the display unit; and
a communication unit provided in the housing and communicating with outside.

23. An illuminating device comprising:
a light source including the light-emitting device according to claim 1; and
a light diffusion part or an optical film that allows passage of light emitted by the light source.

24. A mobile body comprising:
a lighting fixture including the light-emitting device according to claim 1; and
a body provided with the lighting fixture.

25. A method for manufacturing a light-emitting device, the method comprising the steps of:
forming a reflection portion of a first element and a reflection portion of a second element on a substrate;
forming a first insulating layer of the first element and a second insulating layer of the second element, and forming the first insulating layer of the first element or the second insulating layer of the second element between the reflection portion of the first element and the reflection portion of the second element;
forming a first electrode of the first element and a first electrode of the second element; and
forming a conductor on the first insulating layer of the first element or the first insulating layer of the second element between the reflection portion of the first element and the reflection portion of the second element.

26. The method for manufacturing the light-emitting device according to claim 25, further comprising a step of forming a third insulating layer between the reflection portion of the first element and the reflection portion of the second element in a plan view of the substrate.
